(19) United States
(12) Patent Application Publication
(10) Pub. No.: US 2006/0145350 A1
(43) Pub. Date: Jul. 6, 2006

(54) High frequency conductors for packages of integrated circuits

(76) Inventor: Harald Gross, Dresden (DE)

Correspondence Address: SLATER & MATSIL LLP, 17950 PRESTON ROAD, SUITE 1000, DALLAS, TX, 75252, US

(21) Appl. No.: 11/026,540

(22) Filed: Dec. 30, 2004

(51) Int. Cl. H01L 23/48

(52) U.S. Cl. 257/762

(57) ABSTRACT

High frequency conductors can be used with packages of integrated circuits. It includes metal traces on the surface of a semiconductor chip with integrated circuits as well as electrical connections of chips in a stack to an interposer or other interfaces which must comply with requirements for high frequencies such as matched impedance or shielded signal propagation. The invention relates also to high frequency conductors perpendicular to the surface of the semiconductor chip to connect metal traces in different planes and a process for manufacturing such metal traces.

### TECHNICAL FIELD

The invention is directed at high frequency conductors for packages of integrated circuits.

### BACKGROUND

Prior art are stacks of chips with integrated circuits that typically employ bonded wires for electrical interconnection to an interposer (which is a substrate with electrical wiring to contact the integrated circuits). These contact-wires are not shielded and effects like cross-talk become more and more significant for next product generations because of the demand for higher operating frequencies.

On the other hand, redistribution layers on the surface of a chip must have a low impedance to minimize signal loss or other adverse effects. Thus thicker layers are usually preferable in respect to electrical performance. Contrary to the improved electrical performance are higher costs to fabricate thicker layers.

Well known in the prior art is the so called skin effect, which means electrical current flows at high frequencies only at the peripheral region, the wall region, of a conductor. Therefore, hollow conductors are utilized for alternating currents at high frequencies. Such hollow conductors show the same electrical performance compared to solid conductors of the same diameter.

### SUMMARY OF THE INVENTION

The invention is directed at high frequency conductors for packages of integrated circuits. It includes metal traces on the surface of a semiconductor chip with integrated circuits as well as electrical connections of chips in a stack to an interposer or other interfaces which must comply with requirements for high frequencies such as matched impedance or shielded signal propagation. The invention relates also to high frequency conductors perpendicular to the surface of the semiconductor chip to connect metal traces in different planes and a process for manufacturing such metal traces.

In one aspect, the invention provides electric conductors between integrated circuits and contact pads suitable for conducting alternating electrical currents at high frequencies.

In another aspect, the invention provides conductors (bare metal traces) for rerouting of contact pads of integrated circuits with an impedance that is matched to a printed circuit board to minimize signal reflection.

In a further aspect, the invention reduces signal loss or other effects of metal traces at higher frequencies.

In a further aspect, the invention realizes high frequency conductors for packages of integrated circuits.

In yet another aspect, the invention provides shielded electric conductors perpendicular to the surface of an integrated circuit chip (vias) in package.

The preferred embodiment of the invention provides a high frequency conductor for packages of integrated circuits comprising a carrier that can be a silicon wafer, a dielectric layer on the surface of the carrier, a metal trace on the surface of the dielectric layer to connect contact pads of the integrated circuit with other functional elements, and whereby the metal trace consists at least of copper.

In one embodiment, each conductor is provided with a ground shield.

In another embodiment the ground shield is made of a metal positioned in horizontal direction at both sides beside the conductor.

The space between the conductor and the ground shield may be filled with an isolating material, such as an epoxy based resist or a polyimide.

Embodiments of the invention also provide a high frequency conductor for packages of integrated circuits comprising a carrier which can be a silicon wafer, a dielectric layer on the surface of the carrier, a metal trace on the surface of the polyimide or isolation layer to connect contact pads of the integrated circuit with other functional elements, and whereby the metal trace consists at least of copper or a stack of copper, nickel and gold as coverage, wherein the metal trace is connected with a metallized via for signal transfer perpendicular to the surface of the carrier and wherein the metallization in the via is performed by electroplating such that only the inner wall of the via is coated with a metal layer.

The metal layer may be copper or a stack of copper, nickel and gold as a protective layer.

In one embodiment, the metal layer within the via is surrounded by a ground shield, which can be a metal layer.

### BRIEF DESCRIPTION OF THE DRAWINGS

For a more complete understanding of the present invention, and the advantages thereof, reference is now made to the following descriptions taken in conjunction with the accompanying drawing, in which:

FIGS. 1A-1F show a sequence for producing a shielded bare metal trace on the surface of a semiconductor chip;

FIG. 2A shows a cross section of a typical metal trace without shielding on the surface of a semiconductor chip (prior art);

FIG. 2B shows a top view of FIG. 2A;

FIG. 3 shows a shielded metal trace on the surface of a semiconductor chip (prior art);

FIG. 4A shows a cross section of a metal trace design according to the invention suitable for alternating high frequency currents;

FIG. 4B shows a top view of FIG. 4A;

FIG. 5A shows a cross section of a metal trace perpendicular to the chip surface (via) according to the invention suitable for alternating high frequency currents; and

FIG. 5B shows a top view of FIG. 5A.

### DETAILED DESCRIPTION OF ILLUSTRATIVE EMBODIMENTS

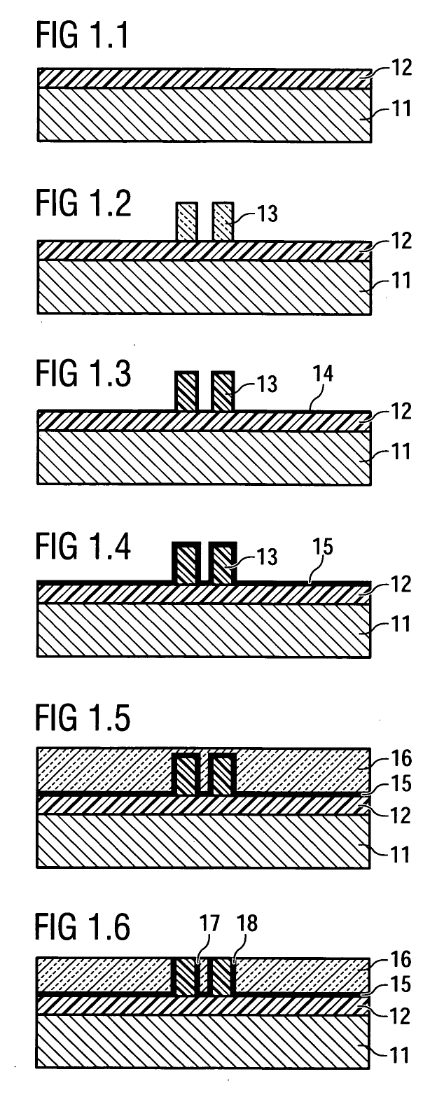

FIGS. 1A-1F show a simplified sequence for producing a shielded bare metal trace on the surface of a semiconductor chip. FIG. 1A depicts a part of chip on a silicon wafer with a bulk silicon 11 with an integrated circuit on surface. This surface is covered by a polymer layer 12 for mechanical protection and electrical isolation.

The steps for producing a shielded bare trace are first a lithography step to define traces. FIG. 1B illustrates an epoxy based photo resist structure 13, e.g., 40 μm high (lines and spaces may be 10 μm wide each) structured by well-known photolithography steps.

Referring to FIG. 1C, a seed layer 14 can be coated by sputter coating of surface the structure 13 with seed layer, e.g., 50 nm Ti/150 nm Cu as basis for electroplating of Cu as illustrated in FIG. 1D. The electroplated layer 15 has a thickness of about 3.5 μm Cu.

The realized structure is then coated and levelled with an epoxy resin 16, which can be the same (or different) material as used for the structure 13. The result is shown in FIG. 1E. As shown, electroplated layer 15 is preferably completely embedded in the resin layer 16.

The final step is grinding the upper surface of epoxy resin 16 until metal on top is exposed. Upper surfaces of the metal 15 can form a U-shaped HF-conductor 17 (HF=high frequency) that is realized with metal shields 18 on the left and right sides of the HF-conductor 17. The conductor 17 is embedded and stabilized in epoxy resin. The metal shields 18 can be connected with ground or another suitable potential.

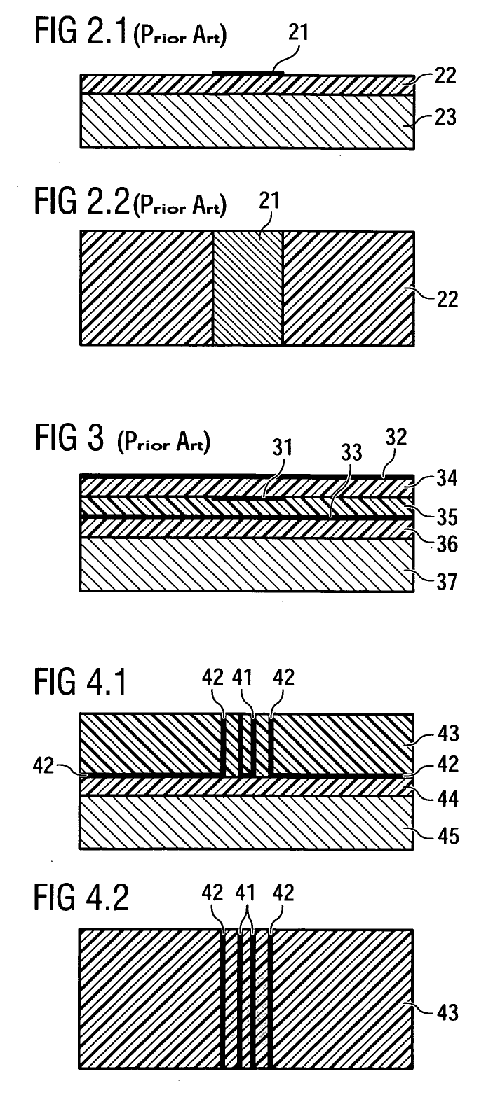

FIGS. 2A, 2B and 3 illustrate the prior art with microstrip lines 21 without shielding deposited on a polymer layer 21 which is used for mechanical protection and electrical isolation of a bulk silicon 23 with an integrated circuit on the surface (FIG. 2A). FIG. 2B shows a top view on the structure of FIG. 2A.

FIG. 3 (prior art) is a schematic illustration of a shielded microstrip line 31 on a bulk silicon 37 with an integrated circuit on the surface. The microstrip line 31 is embedded in dielectric layers 34 and 35, e.g., a polymer, and is shielded by a lower metal layer 33 below the dielectric layer 35 and an upper layer 32 above the dielectric layer 34. Between the bulk silicon 37 and the lower metal layer 33 is deposited a dielectric polymer 36 for mechanical protection and electrical isolation.

FIG. 4A shows a cross section of a shielded U-shaped microstrip line 41 on surface on bulk silicon 45 covered by a dielectric layer 44, e.g., a polymer. On this structure are deposited a metal layer 42 for shielding and a U-shaped microstrip line 41 both realized at a similar manner as described in connection with the FIGS. 1A to 1F. FIG. 4B shows a top view of FIG. 4A.

Since the skin depth of current at high frequencies is about 3 μm the electroplating of 3 μm is enough. The result is a larger surface area with lower impedance and the resistance might be higher. Another effect is saving of copper.

For example at frequencies of about 500 MHz the skin depth in copper for signal propagation is only 2.9 μm. It becomes even smaller at higher frequencies. Thus, a hollow conductor with a wall thickness of about 2.9 μm and a diameter of about 100 μm shows the same impedance value as a solid conductor of the same diameter in first order.

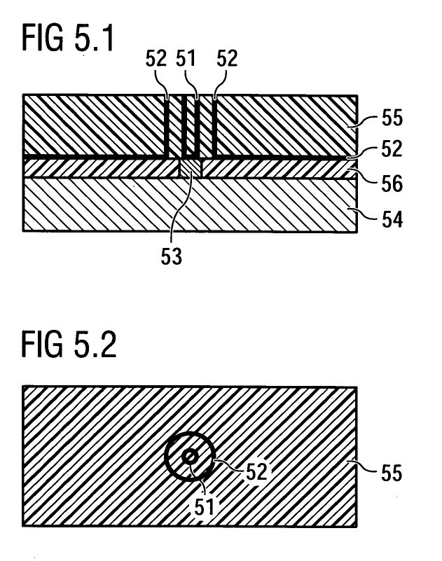

FIGS. 5A and 5B illustrate a shielded via as interconnection of chips in a stack. The basis is a silicon chip 54 with integrated circuit and a top dielectric layer 56 with an embedded contact pad 53 on the surface of the integrated circuit. The contact pad 53 is connected with an HF-conductor 51, which is surrounded by a grounded metal shield 52. Both the HF-conductor 51 and the grounded metal shield 52 are embedded in a polymer 55 for electrical isolation (FIG. 5A).

FIG. 5B depicts a top view at the embodiment of FIG. 5A with an HF-conductor 51 surrounded by a grounded metal shield 52 and embedded in a dielectric layer 56, e.g., a polymer.

Both examples have additional ground shields to prevent cross talk to other wires or radio signals. A person skilled in the art will be able to modify the described original process flow of the examples.

Since the skin depth of current at high frequencies is about 3 μm the electroplating of 3 μm is enough. The result is a larger surface area with lower impedance and the resistance might be higher.

For example, at frequencies of about 500 Mhz the skin depth in copper for signal propagation is only 2.9 μm. It becomes even smaller at higher frequencies. Thus, a hollow conductor with a wall thickness of 2.9 μm and a diameter of 100 μm becomes the same impedance value as a solid conductor of the same diameter in first order.

What is claimed is:

1. A high frequency conductor for packages of integrated circuits, the high frequency conductor comprising:
a carrier with an integrated circuit;
an isolation layer on a surface of the carrier;
a metal trace on a surface of the isolation layer to connect contact pads of the integrated circuit with other functional elements, wherein the metal trace comprises a U-shaped cross section with outer dimensions corresponding with a solid metal trace.

2. The high frequency conductor of claim 1, wherein the metal trace comprises copper.

3. The high frequency conductor of claim 2, wherein the metal trace comprises a stack of copper, nickel and gold.

4. The high frequency conductor of claim 1, wherein said electrical conductor is divided into some electrical conductors each with a U-shaped cross section so that the electrical conductors are positioned side by side with a distance between them and whereby the outer dimensions of the conductors are equal with a solid metal trace.

5. The high frequency conductor of claim 1, wherein each conductor with the U-shaped cross section is provided with a ground shield.

6. The high frequency conductor of claim 5, wherein the ground shield is made of a metal positioned in horizontal direction at both sides beside the conductor with the U-shaped cross section.

7. The high frequency conductor of claim 6, wherein a space between the conductor with the U-shaped cross section and the ground shield is filled with an isolating material.

8. The high frequency conductor of claim 7, wherein the isolating material comprises a resist.

9. The high frequency conductor of claim 7, wherein the isolating material comprises a polyimide.

10. A method for manufacturing a high frequency conductor for packages of integrated circuits, the method comprising:
defining an insulator structure over a substrate, the insulator structure including an upper surface and sidewall surfaces;
depositing a metal layer on the upper surface and sidewall surfaces of the insulator structure;
coating the metal layer with insulating material; and
grinding an upper surface of the insulating material until metal on top is exposed and a U-shaped HF-conductor is realized with metal shields on left and right sides of the HF-conductor, the U-shaped HF conductor embedded and stabilized in the insulating material.

11. The method of claim 10, wherein depositing a metal layer comprises:
coating the upper surface and sidewall surfaces of the insulator structure with a seed layer; and
electroplating the seed layer with a copper layer.

12. The method of claim 11, wherein the copper layer is formed with a thickness of about 3.5 μm.

13. The method of claim 11, wherein the seed layer is deposited on the insulator structure with a thickness of about 50 nm Ti and 150 nm Cu.

14. The method of claim 10, wherein the insulator structure comprises an epoxy based photoresist.

15. The method of claim 14, wherein the insulating material comprises the same material as the insulator structure.

16. A semiconductor device comprising:
integrated circuitry disposed within a semiconductor substrate;
a metal layer overlying an upper surface of the semiconductor substrate, a first portion of the metal layer electrically coupled to a contact region of the integrated circuitry and a second portion of the metal layer serving as a shield;
a first metal extension electrically coupled to the first portion of the metal layer and extending outwardly from the upper surface; and
a second metal extension electrically coupled to the second portion of the metal layer and extending outwardly from the upper surface, the second metal extension substantially surrounding the first metal extension.

17. The device of claim 16, wherein the metal layer comprises copper, wherein the first metal extension comprises copper and wherein the second metal extension comprises copper.

18. The device of claim 16, wherein the integrated circuitry operates at frequencies greater than about 500 MHz and wherein the first metal extension has a thickness no greater than about 3 μm.

19. The device of claim 16 and further comprising an insulating material disposed over the metal layer such that the first and second metal extensions are embedded within the insulating material.

20. The device of claim 16, wherein the first metal extension extends outwardly from the upper surface at an angle of about 90° relative to the upper surface and wherein the second metal extension extends outwardly from the upper surface in a direction substantially parallel to the first metal extension.
